(19) United States
(12) Patent Application Publication
(10) Pub. No.: US 2011/0242739 A1
(43) Pub. Date: Oct. 6, 2011

(54) SLIDING APPARATUS FOR ELECTRONIC DEVICE

(75) Inventor: WEN-BIN SHEN, Tu-Cheng (TW)

(73) Assignee: HON HAI PRECISION INDUSTRY CO., LTD., Tu-Cheng (TW)

(21) Appl. No.: 12/830,531

(22) Filed: Jul. 6, 2010

(30) Foreign Application Priority Data
Mar. 31, 2010 (TW) 99205604

(51) Int. Cl. H05K 5/00; F16C 19/00

(52) U.S. Cl. 361/679.01; 384/51

(57) ABSTRACT

A sliding apparatus includes a first sliding member and a second sliding member slidable relative to the first sliding member. The second sliding member includes two sliding paths. Each sliding path includes a number of positioning portions along a sliding direction relative to the first sliding member. Two positioning assemblies are slidably mounted in the first sliding member and are slidably mounted in the sliding paths of the second sliding member to position the second sliding member relative to the first sliding member.

### CROSS-REFERENCE TO RELATED APPLICATION

Relevant subject matter is disclosed in a co-pending U.S. patent application (Attorney Docket No. US30307) filed on the same date and entitled “SLIDING APPARATUS FOR ELECTRONIC DEVICE,” and assigned to the same assignee as this patent application.

### BACKGROUND

1. Technical Field

The present disclosure relates to a sliding apparatus and, particularly to a sliding apparatus used for an electronic device having a slidable display.

2. Description of Related Art

Usually, displays of electronic devices are slidable for convenient operation and to save space. For example, a mobile phone generally has a main body and a slidable display mounted to the main body by a sliding apparatus. The display slides to a predetermined position, and then stays in this position. However, the traditional sliding apparatus can position the display at only one predetermined position relative to the main body.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an embodiment of a sliding apparatus.

FIG. 2 is an inverted view of FIG. 1.

FIG. 3 is an exploded, isometric view of the sliding apparatus of FIG. 1, the sliding apparatus including a sliding member and a sliding element.

FIG. 4 is an inverted view of FIG. 3.

FIG. 5 is an enlarged, isometric view of the sliding member of FIG. 3.

FIG. 6 is an enlarged, isometric view of the sliding element of FIG. 3.

FIGS. 7-10 are different views of different states of the sliding apparatus of FIG. 1.

FIG. 11 is a sketch view of an electronic device using the sliding apparatus.

### DETAILED DESCRIPTION

The disclosure, including the accompanying drawings in which like references indicate similar elements, is illustrated by way of examples and not by way of limitation. It should be noted that references to “an” or “one” embodiment in this disclosure are not necessarily to the same embodiment, and such references mean at least one.

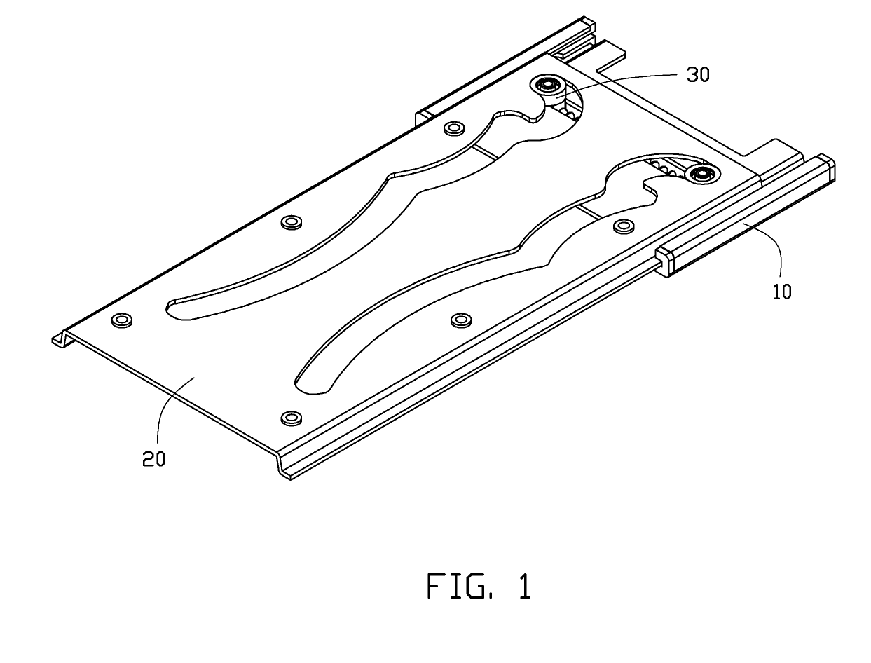

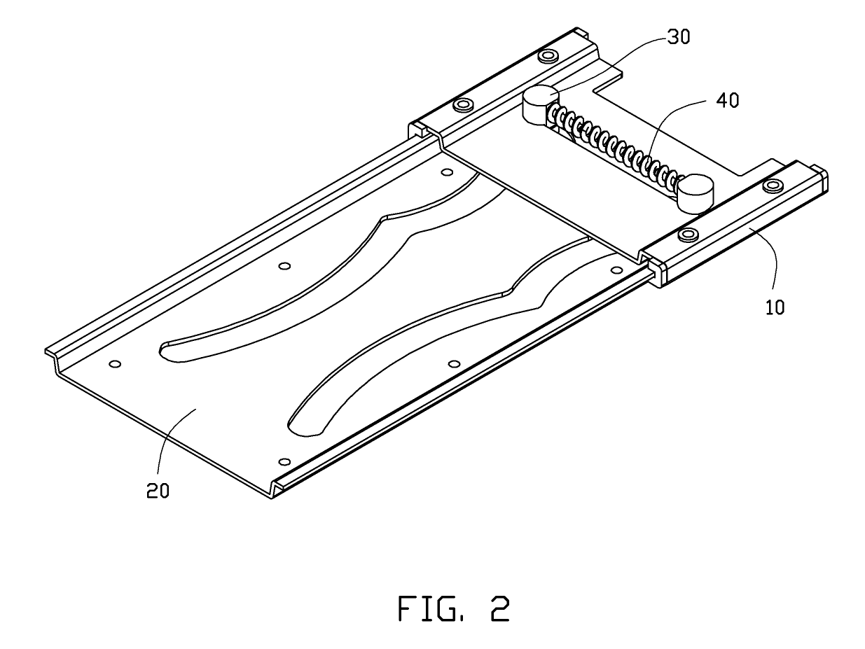

Referring to FIGS. 1 and 2, one embodiment of a sliding apparatus includes a first sliding member 10, a second sliding member 20, two positioning assemblies 30, and a resilient member 40. In this embodiment, the resilient member 40 is a coil spring.

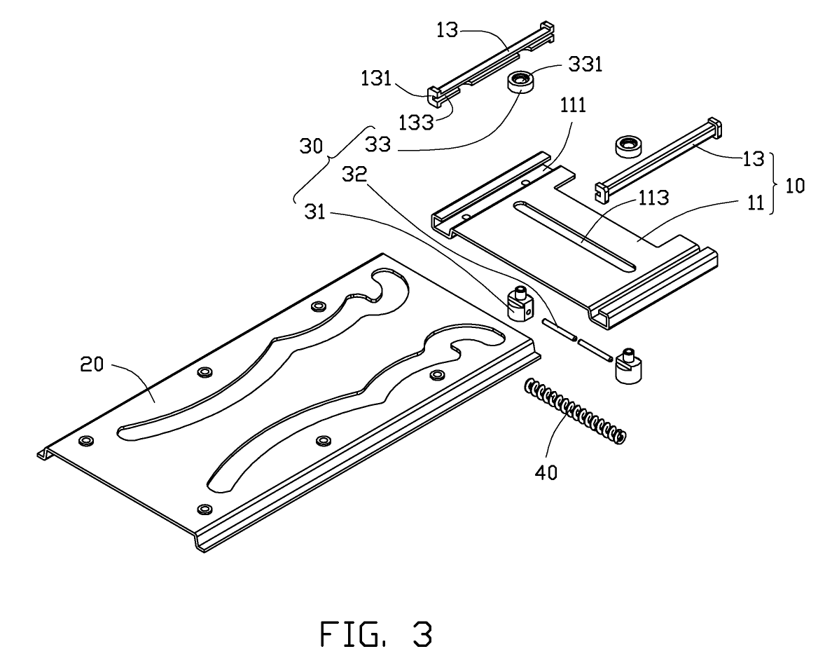

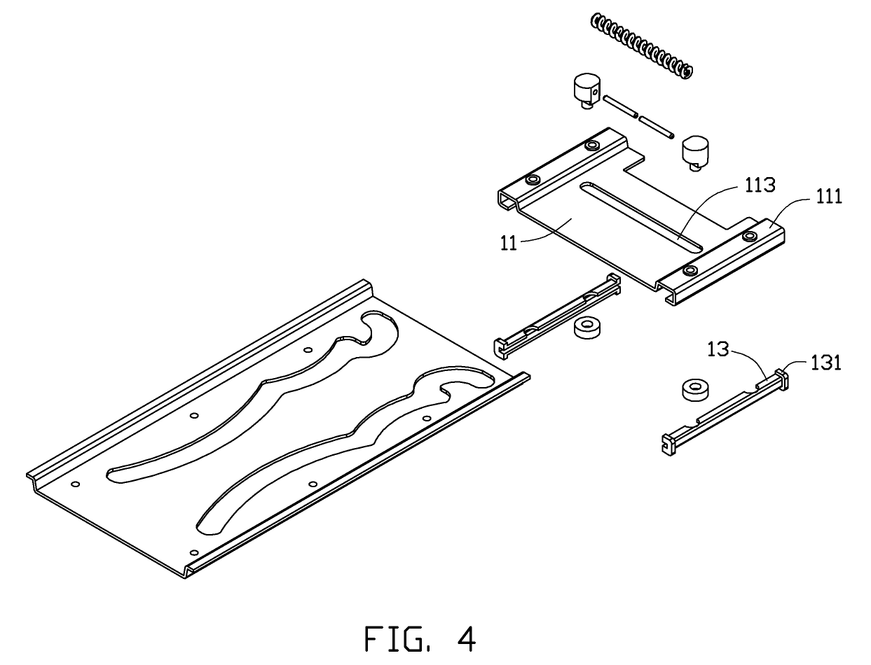

Referring to FIGS. 3 and 4, the first sliding member 10 includes a main body 11 and two sliding portions 13 mounted to opposite ends of the main body 11. The main body 11 can be plate shaped, each end of which is deformed to bind a receiving portion 111 which can have a substantial C-shaped cross-section. An opening is formed between each receiving portion 111 and the main body 11. The main body 11 defines a sliding slot 113 substantially perpendicular to the sliding direction of the second sliding member 20 relative to the first sliding member 10, in a middle portion of the main body 11. Each end of each sliding portion 13 forms a limiting block 131. Each of the sliding portions 13 can define a substantially U-shaped channel 133 along a longitudinal direction of the sliding portion 13. Each of the sliding portions 13 is mounted in a corresponding receiving portion 111 through the opening of the main body 11. The limiting blocks 131 of each of the sliding portions 13 resist against two opposite ends of the corresponding receiving portion 111, to sandwich the receiving portion 111.

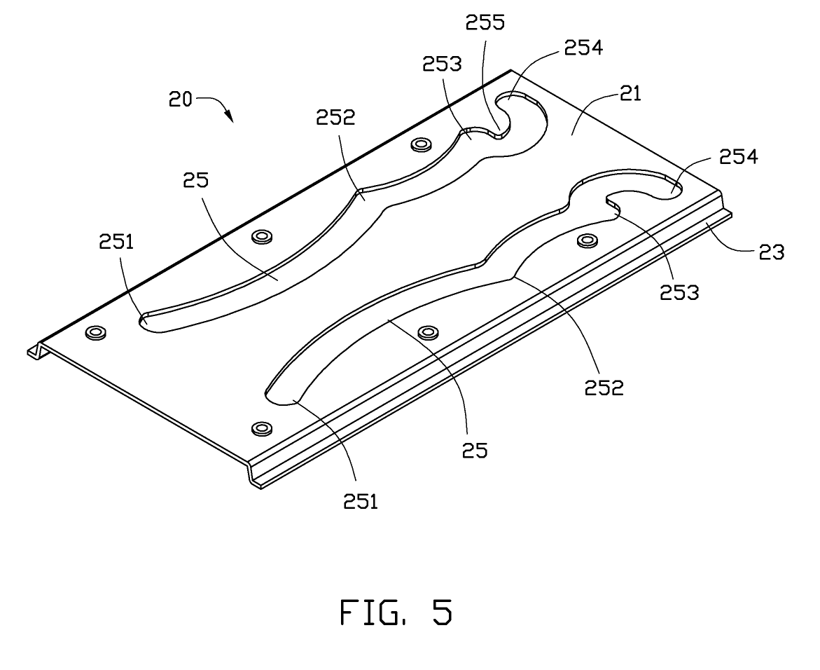

Referring to FIG. 5, the second sliding member 20 can be plate shaped, and includes a main plate 21 and two substantially parallel sliding rails 23 formed at two opposite sides of the second sliding member 20. The main plate 21 defines two symmetrical sliding paths 25 along the sliding direction of the second sliding member 20 relative to the first sliding member 10. Each sliding path 25 includes a first positioning portion 251, a second positioning portion 252, a third positioning portion 253, and a fourth positioning portion 254 from a first end to a second end along the sliding direction of the second sliding member 20 relative to the first sliding member 10 in that order. The first positioning portion 251, the second positioning portion 252, and the third positioning portion 253 together can form a W-shape whose opening turns towards a corresponding side of the second sliding member 20. A raised portion 255 is formed between the fourth positioning portion 254 and the third positioning portion 253.

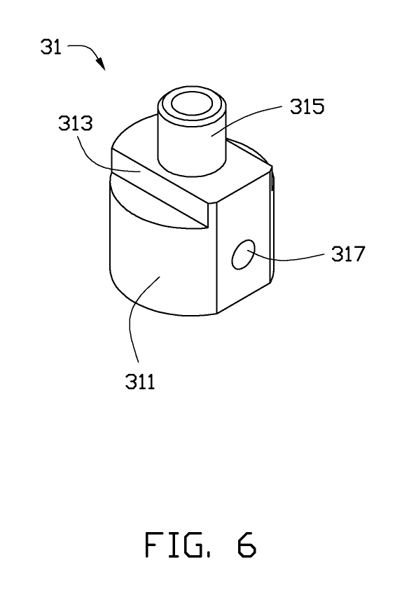

Referring to FIG. 6, each positioning assembly 30 includes a sliding element 31, a limiting member 33, and a pole 32 mounted to a side of the sliding element 31. The sliding element 31 includes a columnar main body 311, a sliding block 313 extending from a top of the main body 311, and a fixing post 315 extending from a top of the sliding block 313. The circumference of the main body 311 defines a mounting hole 317 for fixing the pole 32. The limiting member 33 can be annular shaped, which axially defines a fixing hole 331 for receiving the fixing post 315 of the sliding element 31.

Referring to FIGS. 1 and 2, in assembly, the sliding portions 13 are mounted in the corresponding receiving portions 111 of the first sliding member 10. The sliding rails 23 of the second sliding member 20 are slidably received in the corresponding channels 133 of the sliding portions 13. The resilient member 40 is sleeved around the poles 32 of the positioning assemblies 30. The fixing post 315 of the sliding element 31 of each positioning assembly 30 extends through the sliding slot 113 of the first sliding member 10 and the fourth positioning portion 254 of a corresponding sliding path 25 of the second sliding member 20. The limiting members 33 are fixed to a distal end of the fixing posts 315 of the corresponding sliding elements 31.

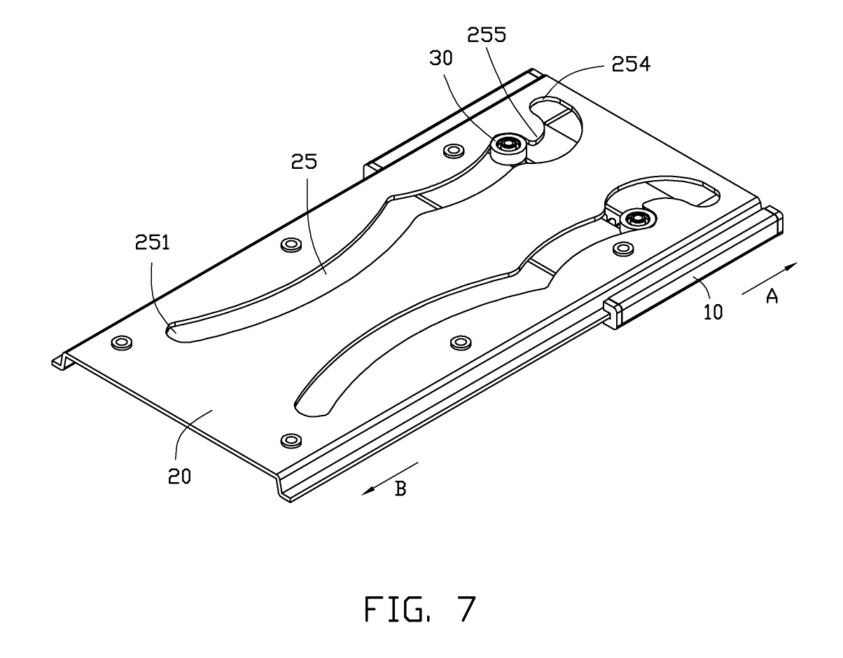

FIGS. 7 to 10 are views of different states of the sliding apparatus. After assembly, the second sliding member 20 slides along the ‘A’ direction relative to the first sliding member 10, to drive the positioning assemblies 30 to ride over the raised portions 255 of the sliding paths 25 and enters the sliding paths 25 between the first positioning portion 251 and the third positioning portion 253.

FIG. 7 shows one state of the sliding apparatus, wherein the resilient member 40 restores to position the limiting members 33 in the third positioning portions 253.

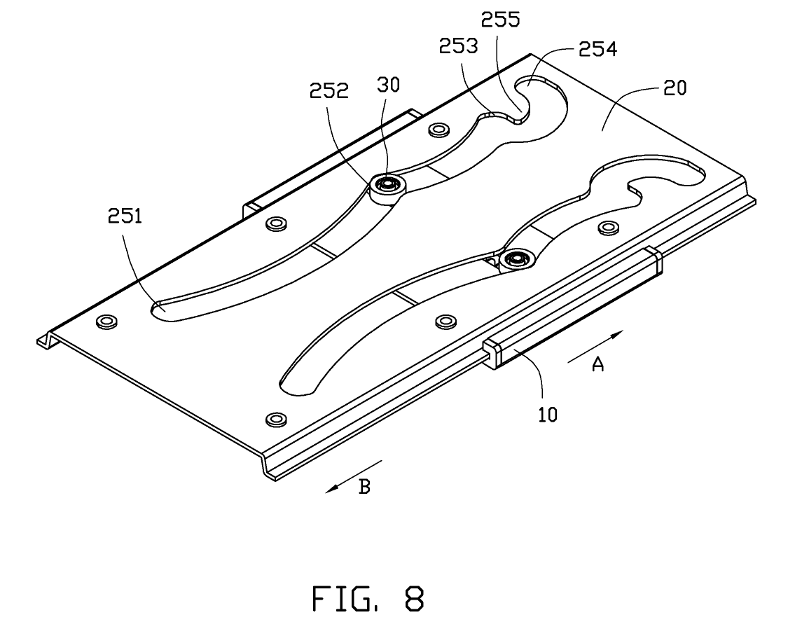

While sliding the second sliding member 20 along the ‘A’ direction, the positioning assemblies 30 slide in the slide path 25 between the third positioning portions 253 and the second positioning portions 252 to compress the resilient member 40. The positioning assemblies 30 ride over the highest portion of the slide path 25 between the third positioning portions 253 and the second positioning portions 252. The resilient member 40 then restores to drive the positioning assemblies 30 to slide to position in the second positioning portions 252, as shown in FIG. 8.

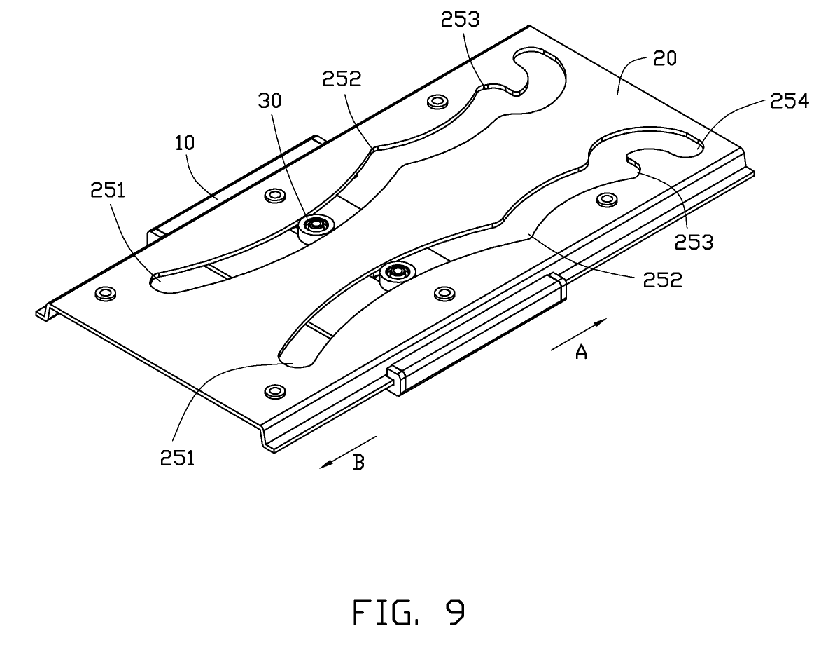

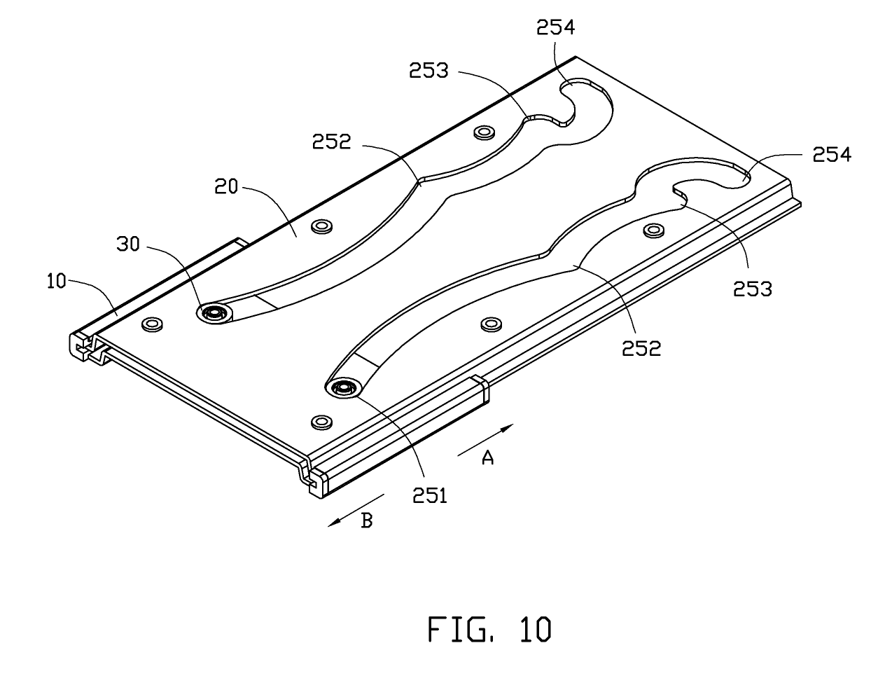

While sliding the second sliding member 20 along the ‘A’ direction, the positioning assemblies 30 slide in the slide path 25 between the second positioning portions 252 and the first positioning portions 251 to compress the resilient member 40. The positioning assemblies 30 ride over the highest portion of the slide path 25 between the second positioning portions 252 and the first positioning portions 251, as shown in FIG. 9. The resilient member 40 then restores to drive the positioning assemblies 30 to slide to be positioned in the first positioning portions 251, as shown in FIG. 10.

When the second sliding member 20 slides relative to the first sliding member 10 along the ‘B’ direction, opposite to the ‘A’ direction, the acting principle is the same as when the second sliding member 20 is slid relative to the first sliding member 10 along the ‘A’ direction.

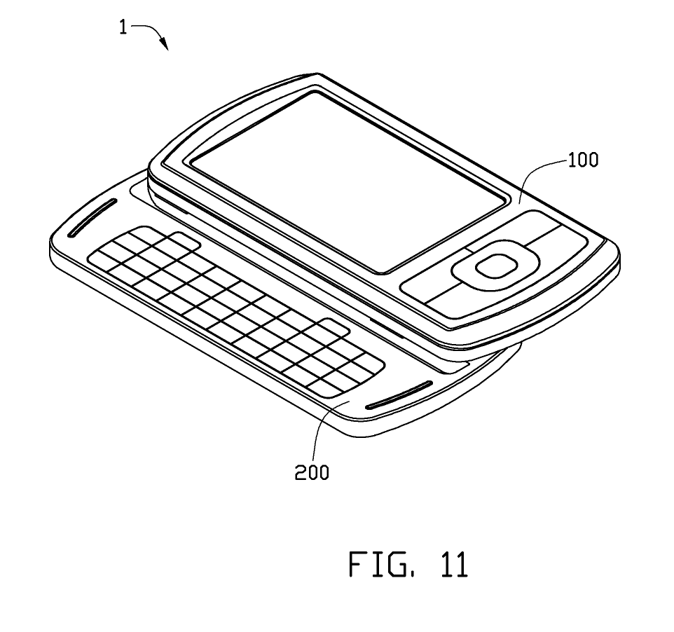

Referring to FIG. 11, when the sliding apparatus is utilized in an electronic device 1, the first sliding member 10 and the second sliding member 20 are respectively mounted to a display 100 and a base 200 of the electronic device 1. If the second positioning portion 252 of the sliding path 25 is set as an original position, wherein the display 100 and the base 200 are completely overlapping each other, the display 100 of the electronic device 1 can slide along the ‘A’ and ‘B’ directions relative to the base 200. If the first positioning portion 251 of the sliding path 25 is set as an original position, wherein the display 100 and the base 200 are completely overlapping each other, the display 100 of the electronic device 1 can slide along the ‘A’ direction relative to the base 200 and be positioned twice. If the third positioning portion 253 of the sliding path 25 is set as an original position, wherein the display 100 and the base 200 are completely overlapping each other, the display 100 of the electronic device 1 can slide along the ‘B’ direction relative to the base 200 and be positioned twice.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A sliding apparatus, comprising:
a first sliding member comprising two sliding portions formed at opposite ends and a sliding slot defined in a middle portion;
a second sliding member comprising two substantially parallel sliding rails formed at two opposite sides to be slidably received in the sliding portions, and two sliding paths, each sliding path comprising a first positioning portion, a second positioning portion, and a third positioning portion from a first end to a second end along a sliding direction relative to the first sliding member in that order;
two positioning assemblies slidably mounted in the sliding slot of the first sliding member and slidably mounted in the sliding paths of the second sliding member; and
a resilient member positioned between the positioning assemblies to bias the positioning assemblies to position in the first positioning portions, the second positioning portions, or the third positioning portions of the second sliding member.

2. The sliding apparatus of claim 1, wherein the sliding slot of the first sliding member is substantially perpendicular to the sliding direction of the second sliding member relative to the first sliding member.

3. The sliding apparatus of claim 1, wherein the sliding paths of the second sliding member are substantially symmetrical to each other, and defined along the sliding direction of the second sliding member relative to the first sliding member.

4. The sliding apparatus of claim 1, wherein each sliding path between the first positioning portion and the third positioning portion has a W-shape.

5. The sliding apparatus of claim 1, wherein each of the sliding paths further comprises a fourth positioning portion at the second end of the second sliding member, and a raised portion is formed between the fourth positioning portion and the third positioning portion.

6. The sliding apparatus of claim 5, wherein the positioning assemblies are assembled to the second sliding member through the fourth positioning portion and then ride over the raised portion to slide in the sliding paths.

7. The sliding apparatus of claim 1, wherein each of the positioning assemblies comprises a sliding element, a limiting member, and a pole mounted to a side of the sliding element; the resilient member is fixed around the poles of the positioning assemblies.

8. The sliding apparatus of claim 7, wherein the sliding element comprises a columnar main body, a sliding block extending from a top of the main body, and a fixing post extending from a top of the sliding block; the limiting member is annular shaped, and defines a fixing hole for receiving the fixing post.

9. The sliding apparatus of claim 8, wherein the fixing post of the sliding element of each positioning assembly extends through the sliding slot of the first sliding member and a corresponding sliding path of the second sliding member, the limiting members are fixed to distal ends of corresponding fixing posts of the sliding element.

10. The sliding apparatus of claim 1, wherein the resilient member is a coil spring.

11. An electronic device comprising:
a display;
a first sliding member fixed to the display, the first sliding member comprising two sliding portions formed at opposite ends and a sliding slot defined in a middle portion;
a base;
a second sliding member fixed to the base, the second sliding member comprising two substantially parallel sliding rails formed at two opposite sides and slidaly mounted to the sliding portions, and two sliding paths, wherein each sliding path comprises a first positioning portion, a second positioning portion, and a third positioning portion from a first end to a second end along a sliding direction relative to the first sliding member in that order;
two positioning assemblies slidably mounted in the sliding slot of the first sliding member and slidably mounted in the sliding paths of the second sliding member; and
a resilient member positioned between the positioning assemblies to bias the positioning assemblies to position in the first positioning portions, the second positioning portions, or the third positioning portions of the second sliding member.

12. The electronic device of claim 11, wherein the sliding slot of the first sliding member is substantially perpendicular to the sliding direction of the second sliding member relative to the first sliding member.

13. The electronic device of claim 11, wherein the sliding paths of the second sliding member are substantially symmetrical to each other and defined along the sliding direction of the second sliding member relative to the first sliding member.

14. The electronic device of claim 11, wherein each sliding path between the first positioning portion and the third positioning portion has a W-shape.

15. The electronic device of claim 11, wherein each of the sliding paths further comprises a fourth positioning portion at the second end of the second sliding member, and a raised portion is formed between the fourth positioning portion and the third positioning portion.

16. The electronic device of claim 15, wherein the positioning assemblies are assembled to the second sliding member through the fourth positioning portion and then ride over the raised portion to slide in the sliding paths respectively.

17. The electronic device of claim 11, wherein each of the positioning assemblies comprises a sliding element, a limiting member, and a pole mounted to a side of the sliding element; the resilient member is fixed around the poles of the positioning assemblies.

18. The electronic device of claim 17, wherein the sliding element comprises a columnar main body, a sliding block extending from a top of the main body, and a fixing post extending from a top of the sliding block; the limiting member is annular shaped, and defines a fixing hole for receiving the fixing post.

19. The electronic device of claim 18, wherein the fixing post of the sliding element of each positioning assembly extends through the sliding slot of the first sliding member and a corresponding sliding path of the second sliding member, the limiting members are fixed to distal ends of corresponding fixing posts of the sliding element.

20. The electronic device of claim 11, wherein the resilient member is a coil spring.
